(19) United States
(12) Patent Application Publication
(10) Pub. No.: US 2025/0329624 A1
(43) Pub. Date: Oct. 23, 2025

(54) Semiconductor Device and Method of Forming Encapsulated Interconnect Structure for Embedded Photonic Bridge Die

(71) Applicant: STATS ChipPAC Pte. Ltd., Singapore (SG)

(72) Inventors: Linda Pei Ee Chua, Singapore (SG); Swain Hong Alfred Yeo, Singapore (SG); Kai Chong Chan, Singapore (SG); Yaojian Lin, Jiangyin (CN)

(73) Assignee: STATS ChipPAC Pte. Ltd., Singapore (SG)

(21) Appl. No.: 18/643,786

(22) Filed: Apr. 23, 2024

(51) Int. Cl. H01L 23/498; H01L 21/48; H01L 23/00; H01L 23/31; H01L 23/48; H01L 25/16

(52) U.S. Cl. CPC H01L 23/49833; H01L 21/486; H01L 25/167; H01L 21/4853; H01L 23/3185; H01L 23/3192; H01L 23/481; H01L 24/16; H01L 24/32; H01L 24/73; H01L 2224/16227; H01L 2224/32137; H01L 2224/32225; H01L 2224/73204

(57) ABSTRACT

A semiconductor device has a first interconnect structure, second interconnect structure, and a semiconductor die disposed between the first interconnect structure and second interconnect structure. The semiconductor die can have a photonic area. An embedded interconnect structure is disposed between the first interconnect structure and second interconnect structure. The embedded interconnect structure has a height sufficient to span a gap between the first interconnect structure and second interconnect structure. The embedded interconnect structure can be a plurality of conductive posts, and a second encapsulant deposited around the conductive posts. The embedded interconnect structure can be a plurality of e-bar structures, and a second encapsulant deposited around the e-bar structures. The embedded interconnect structure can also be a plurality of vertical loop wires, and a second encapsulant deposited around the vertical loop wires. A first encapsulant is deposited around the semiconductor die and embedded interconnect structure.

### FIELD OF THE INVENTION

The present invention relates in general to semiconductor devices and, more particularly, to a semiconductor device and method of forming an encapsulated interconnect structure for embedded photonic bridge semiconductor die.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices may contain multiple electrical components, e.g., one or more semiconductor die and myriad discrete components to support the semiconductor die, disposed on one or more substrates to perform necessary electrical functions. Highly integrated packages with several components are commonly referred to as system-in-package (SiP) modules. Sip modules often have multiple semiconductor die designed to communicate with each other at high bandwidths. Conductive traces and other interconnect structures formed at the package level may be insufficient to support the necessary bandwidth.

Many SiP modules utilize bridge die to facilitate high-bandwidth communication between components. Bridge die are semiconductor die that may have no circuits formed in their active surface but have fine-pitched interconnects formed over them. Bridge die can be disposed between two or more other semiconductor die, then the adjacent semiconductor die are connected to each other through the bridge die to increase the available data bandwidth between them.

Some bridge die include photonic circuits. Photonic circuits are light-sensitive to add important functionality to the end units. However, photonic circuits also add significant design constraints to the semiconductor packages being formed because the photonic circuit must be exposed to the outside world to allow the intended stimulus to reach the photonic circuit.

Within the SiP module, multiple semiconductor die can be disposed on a surface of a substrate with a first redistribution layer (RDL) for electrical interconnect and for structural support. An encapsulant is deposited over the semiconductor die, IPDs, and substrate. A second RDL is formed over the encapsulant. It is often necessary to make direct electrical connection through the encapsulant between the first RDL and second RDL. However, photonic semiconductor dies can have a thickness greater than 100 micrometers (μm), excluding RDL, UBM and solder interconnection. The maximum practical height of a conventional conductive post is about 100 mm due to constraints on photoresist thickness. Accordingly, conventional conductive posts may be insufficient to account for the height of the photonic semiconductor die and span the gap between the first RDL and second RDL.

A need exists to provide direct electrical interconnect through the encapsulant between the first RDL and second RDL, given the thickness of the photonic semiconductor die.

### BRIEF DESCRIPTION OF THE DRAWINGS

FIGS. 1a-1c illustrate a semiconductor wafer with a plurality of semiconductor die separated by a saw street;

FIGS. 2a-21 illustrate a process of forming encapsulated interconnect post structures;

FIGS. 3a-3f illustrate a process of forming encapsulated interconnect e-bar structures;

FIGS. 4a-4b illustrate encapsulated interconnect vertical loop structures;

FIGS. 5a-5g illustrate an SiP module with the encapsulated interconnect post structures;

FIG. 6 illustrates the SiP module with the encapsulated interconnect post structures and stiffener;

FIG. 7 illustrates the SiP module with the encapsulated interconnect post structures and top encapsulant;

FIG. 8 illustrates the SiP module with the encapsulated interconnect e-bar structures;

FIG. 9 illustrates the SiP module with the encapsulated interconnect vertical loop structures; and

FIG. 10 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

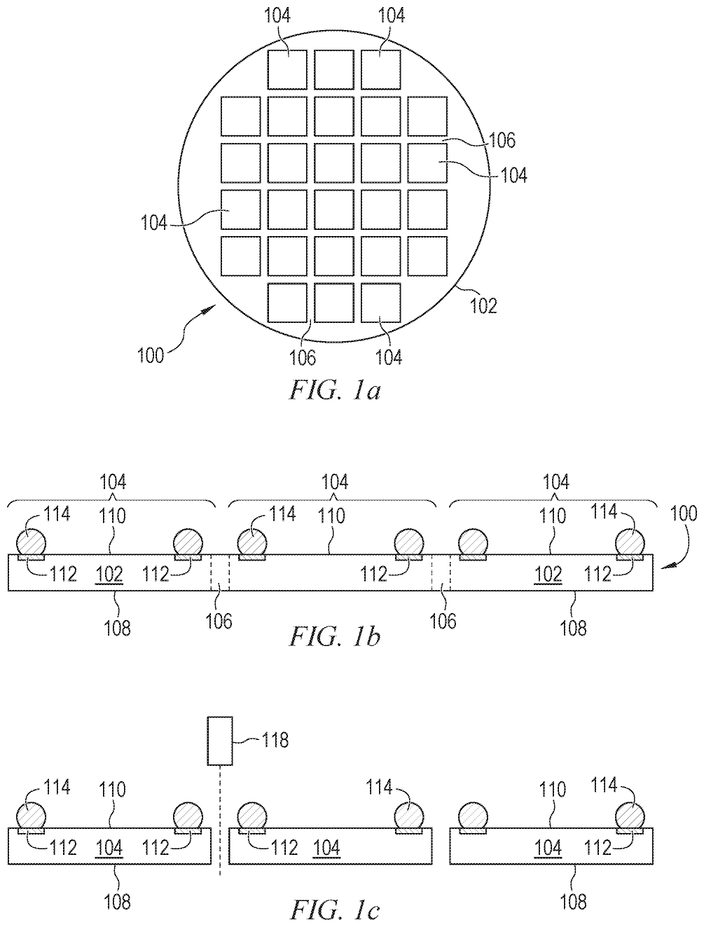

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1c, semiconductor wafer 100 is singulated through saw street 106 using a saw blade or laser cutting tool 128 into individual semiconductor die 104. The individual semiconductor die 104 can be inspected and electrically tested for identification of known good die or unit (KGD/KGU) post singulation.

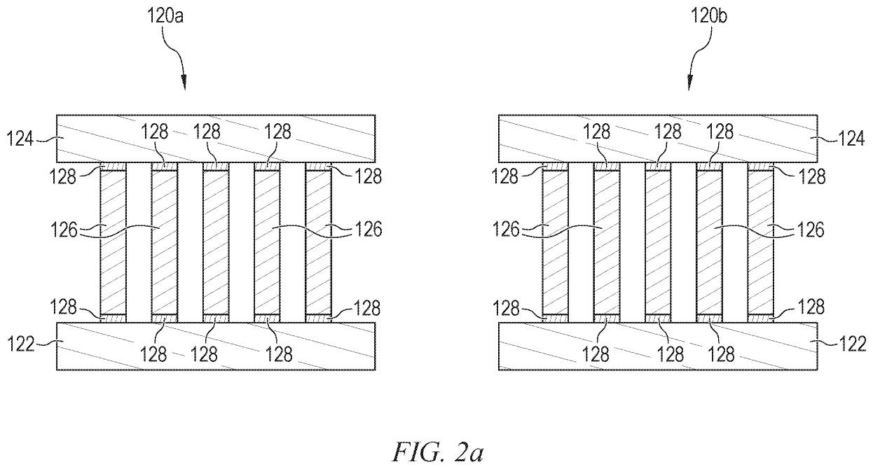

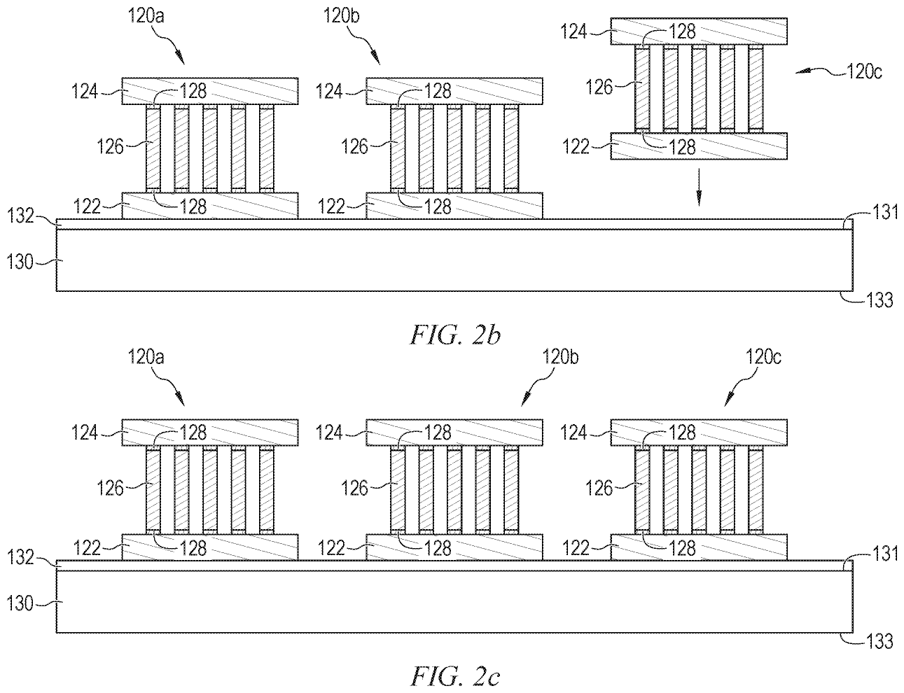

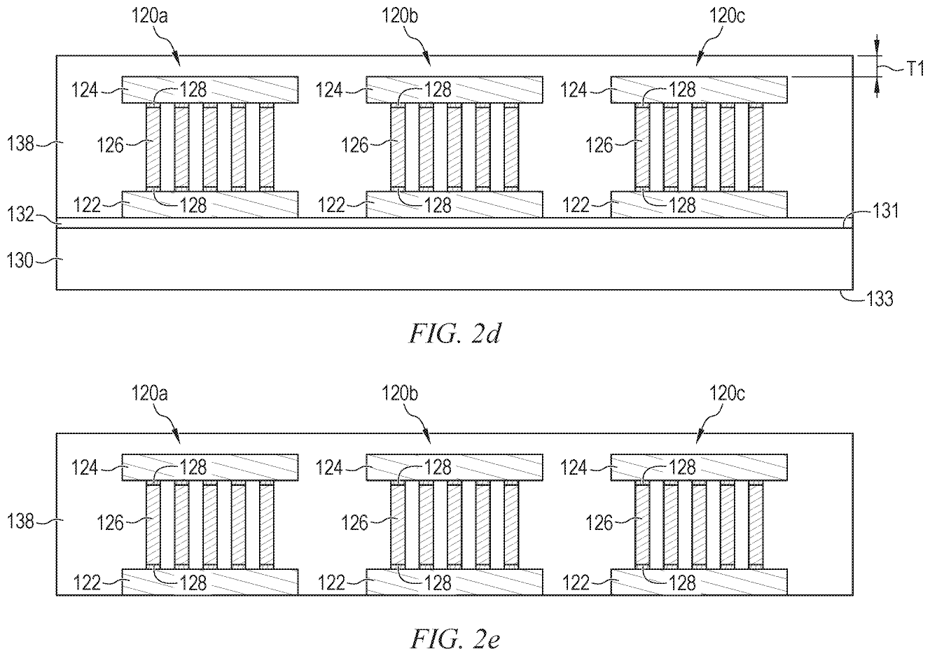

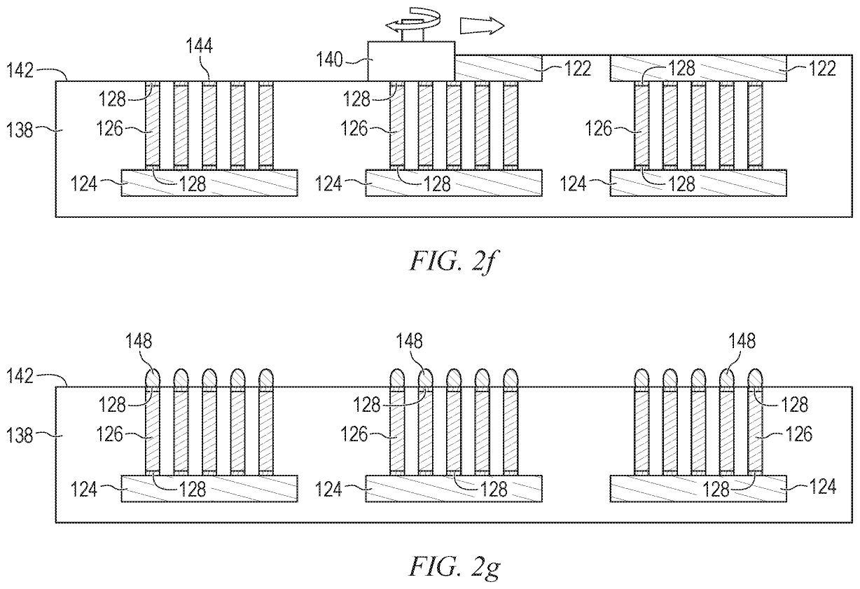

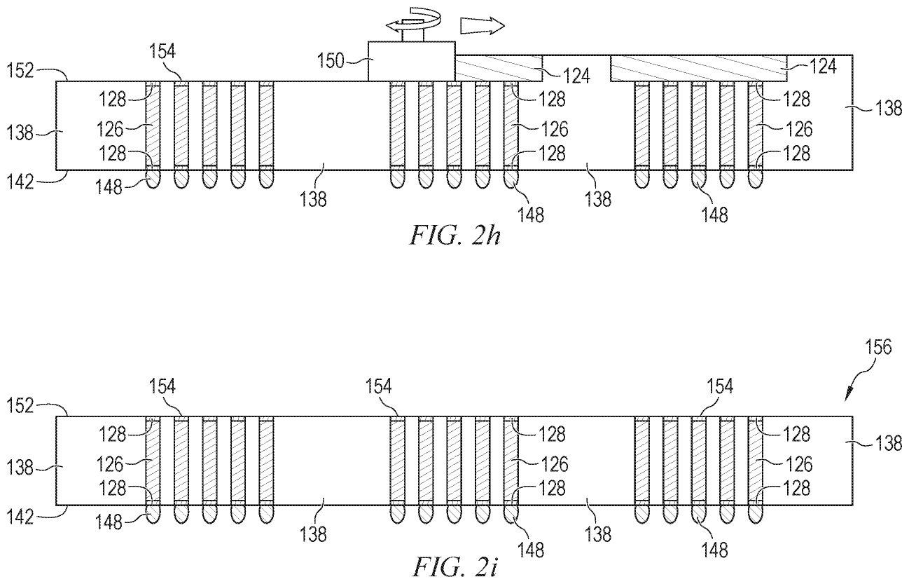

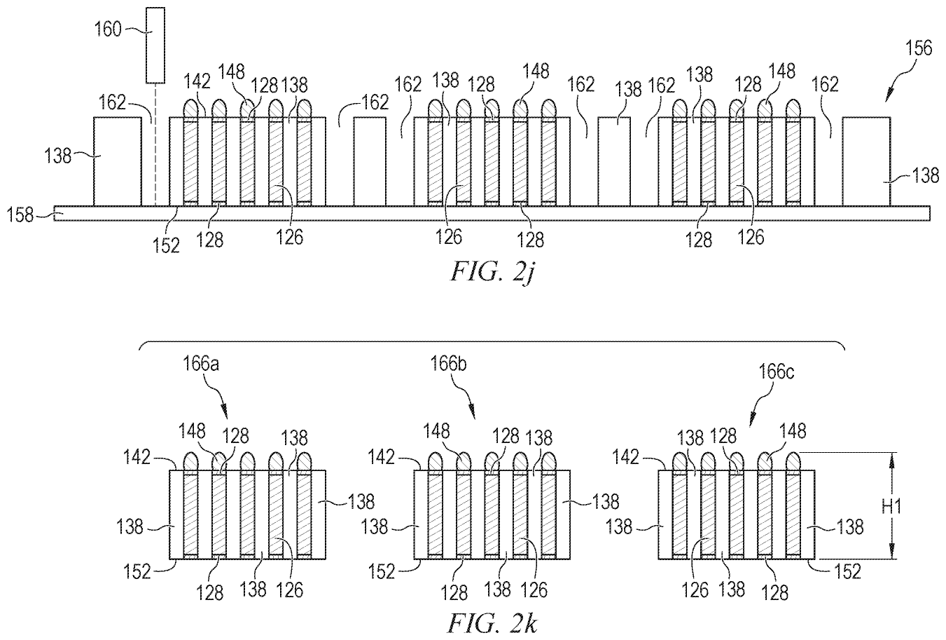

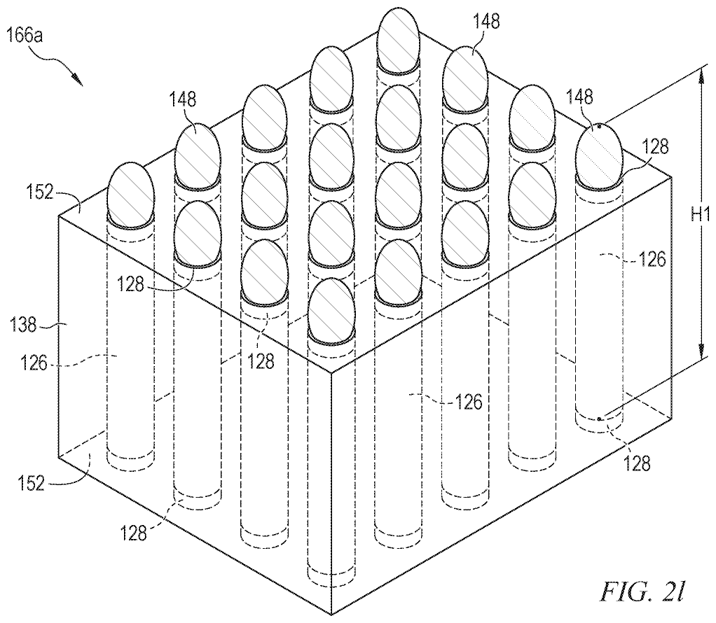

FIGS. 2a-21 illustrate a process of forming encapsulated interconnect post structures. FIG. 2a shows a cross-sectional view of conductive post structures 120a and 120b, each including temporary lower base 122 and upper base 124. Conductive columns or posts 126 are placed between lower base 122 and upper base 124 and bonded with conductive paste or other adhesive 128. Conductive columns or posts 126 can be Al, Cu, Sn, Ni, Au, Ag, or other suitable electrically conductive material. Conductive post structures 120a-120b are typically prefabricated for use in further processing.

FIG. 2b shows a temporary substrate or carrier 130 containing sacrificial base material, such as silicon, polymer, beryllium oxide, glass, metal, or other suitable low-cost, rigid material for structural support. Substrate 130 has major surface 131 and major surface 133, opposite surface 131. In one embodiment, carrier 130 is a support structure with a temporary bonding layer 132 formed over surface 131 of the carrier. Temporary bonding layer 132 can be a double-sided tape.

Conductive post structures 120a-120c are each positioned over substrate 130 using a pick and place operation. Conductive post structure 120c is made similar to conductive post structures 120a-120b from FIG. 2a. Conductive post structures 120a-120c are bonded to bonding layer 132. FIG. 2c shows conductive post structures 120a-120c bonded to substrate 130.

In FIG. 2d, an encapsulant or molding compound 138 is deposited over and around conductive post structures 120a-120c using a paste printing, compressive molding, transfer molding, liquid encapsulant molding, vacuum lamination, spin coating, or other suitable applicator. Encapsulant 138 can be polymer composite material, such as epoxy resin with filler, epoxy acrylate with filler, or polymer with proper filler. Encapsulant 138 is non-conductive, provides structural support, and environmentally protects the semiconductor device from external elements and contaminants. In one embodiment, encapsulant 138 has a thickness T1 over upper base 124 of 20-50 μm.

In FIG. 2e, substrate 130 and bonding layer 132 are removed by chemical etching, chemical mechanical polishing (CMP), mechanical peel-off, mechanical grinding, thermal bake, ultra-violet (UV) light, or wet stripping to expose lower base 122 and encapsulant 138.

In FIG. 2f, the assembly is inverted and lower base 122 and a portion of encapsulant 138 are removed by grinder 140. The grinding operation planarizes surface 142 of encapsulant 138 and exposes surface 144 of conductive column or posts 126 or conductive paste 128.

In FIG. 2g, an electrically conductive bump material is deposited over surface 144 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive posts 126 using a suitable attachment or bonding process. In one embodiment, the bump material is reflowed by heating the material above its melting point to form balls or bumps 148. In one embodiment, bump 148 is formed over an under bump metallization (UBM) having a wetting layer, barrier layer, and adhesive layer. Bump 148 can also be compression bonded or thermocompression bonded to conductive posts 126. Bump 148 represents one type of interconnect structure that can be formed over conductive posts 126. The interconnect structure can also use bond wires, conductive paste, stud bump, micro bump, or other electrical interconnect.

In FIG. 2h, the assembly is inverted and upper base 124 and a portion of encapsulant 138 are removed by grinder 150. The grinding operation planarizes surface 152 of encapsulant 138 and exposes surface 154 of conductive column or posts 126 or conductive paste 128. FIG. 2i shows assembly 156 post-grinding.

In FIG. 2j, assembly 156 is disposed on dicing tape 158. Laser or other cutting tool 160 dices assembly 156 through channels 162 in encapsulant 138 to leave encapsulated interconnect post structures 166a, 166b, and 166c. Dicing tape 158 is removed to produce encapsulated interconnect post structures 166a, 166b, and 166c, as in FIG. 2k. In one embodiment, encapsulated interconnect post structures 166a-166c have a height H1 of 150 μm.

FIG. 2l is a perspective view of encapsulated interconnect post structure 166a with conductive posts 126 embedded within encapsulant 138.

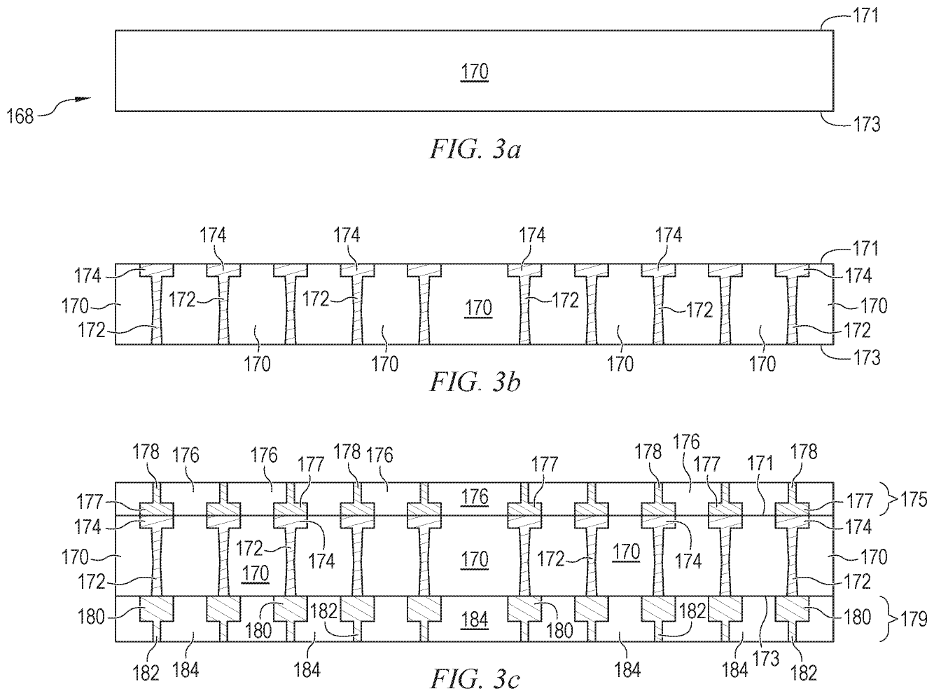

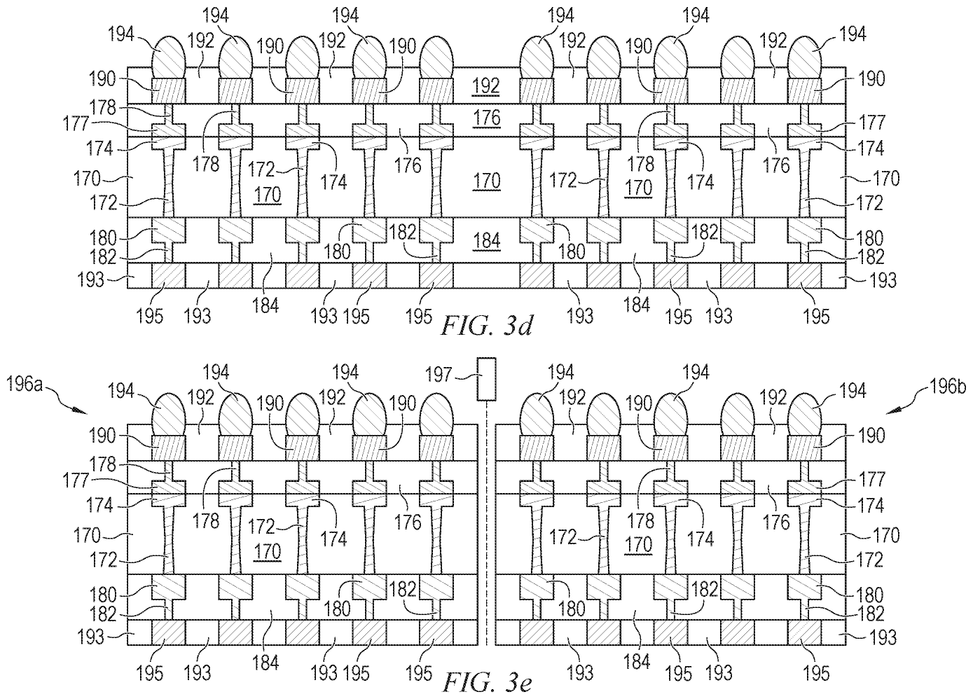

FIG. 3a shows interposer substrate 168 including core material 170, such as silicon, germanium, aluminum phosphide, aluminum arsenide, gallium arsenide, gallium nitride, indium phosphide, silicon carbide, or other bulk material for structural support. Alternatively, core material 170 can be a multi-layer flexible laminate, ceramic, copper clad laminate (CCL), glass, or epoxy molding compound. Core material 170 may contain one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Interposer substrate 168 has a major surface 171 and major surface 173 opposite surface 171.

In FIG. 3b, a plurality of vias is formed through interposer substrate 168 using an etching process or by LDA. The vias are filled with electrically conductive material, such as Al, Cu, Sn, Ni, Au, Ag, or other suitable electrically conductive material, to form conductive vias 172. A portion of interposer substrate 168 is removed from surface 171 using an etching process or by LDA to form a pattern of an RDL. The pattern is filled with electrically conductive material, such as Al, Cu, Sn, Ni, Au, Ag, or other suitable electrically conductive material, to form conductive layer 174 coplanar with surface 171. Alternatively, conductive layer 174 is formed on surface 171 and an insulating layer is added to make the top surface of interposer substrate 168 coplanar. Conductive layer 174 can be formed using PVD, CVD, electrolytic plating, electroless plating process, or other suitable metal deposition process. Portions of conductive layer 174 can be electrically common or electrically isolated depending on the design and function of electrical components attached thereto. In one embodiment, conductive layer 174 is an RDL as it redistributes the electrical signals over and across interposer substrate 168.

In FIG. 3c, interconnect structure 175 is formed over surface 171. Interconnect structure 175 includes insulating layer 176 and conductive layer 177 and conductive vias 178 formed through the insulating layer, similar to conductive vias 172 and conductive layer 174 in FIG. 3b. An interconnect structure 179 is formed over surface 173. Interconnect structure 179 includes conductive layer 180 and conductive vias 182 formed through insulating layer 184, similar to conductive vias 172 and conductive layer 174 in FIG. 3b. Conductive layer 177 and conductive vias 178 are electrically connected to conductive vias 172 and conductive layer 174. Likewise, conductive layer 180 and conductive vias 182 are electrically connected to conductive vias 172 and conductive layer 174.

In FIG. 3d, electrically conductive layer 190 is formed over insulating layer 176 and conductive vias 178 using PVD, CVD, electrolytic plating, electroless plating process, or other suitable metal deposition process. Conductive layer 190 can be one or more layers of Al, Cu, Sn, Ni, Au, Ag, or other suitable electrically conductive material. Portions of conductive layer 190 can be electrically common or electrically isolated depending on the design and function of electrical components attached thereto.

An insulating layer 192 is formed over insulating layer 176 and conductive layer 190. Insulating layer 192 contains one or more layers of SiO2, Si3N4, SiON, Ta2O5, Al2O3, solder resist, polyimide, BCB, PBO, and other material having similar insulating and structural properties. Insulating layer 192 can be formed using PVD, CVD, printing, lamination, spin coating, spray coating, sintering or thermal oxidation. A portion of insulating layer 192 is removed by etching or LDA to expose conductive layer 190.

An electrically conductive bump material is deposited over conductive layer 190 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 190 using a suitable attachment or bonding process. In one embodiment, the bump material is reflowed by heating the material above its melting point to form balls or bumps 194. In one embodiment, bump 194 is formed over a UBM having a wetting layer, barrier layer, and adhesive layer. Bump 194 can also be compression bonded or thermocompression bonded to conductive layer 190. Bump 194 represents one type of interconnect structure that can be formed over conductive layer 190. The interconnect structure can also use bond wires, conductive paste, stud bump, micro bump, or other electrical interconnect.

An insulating layer 193 is formed over insulating layer 184. Insulating layer 193 contains one or more layers of SiO2, Si3N4, SiON, Ta2O5, Al2O3, solder resist, polyimide, BCB, PBO, and other material having similar insulating and structural properties. Insulating layer 193 can be formed using PVD, CVD, printing, lamination, spin coating, spray coating, sintering or thermal oxidation. A portion of insulating layer 193 is removed by etching or LDA to expose conductive vias 182.

An electrically conductive layer 195 is formed over insulating layer 184 and conductive vias 182 using PVD, CVD, electrolytic plating, electroless plating process, or other suitable metal deposition process. Conductive layer 195 can be one or more layers of Al, Cu, Sn, Ni, Au, Ag, or other suitable electrically conductive material. Portions of conductive layer 195 can be electrically common or electrically isolated depending on the design and function of electrical components attached thereto. Conductive layer 195 can be formed prior to insulating layer 193.

In FIG. 3e, the assembly from FIG. 3d is singulated using saw blade or laser cutting tool 197 into interconnect structures 196a and 196b. FIG. 3f shows interconnect structures 196a and 196b post singulation. Encapsulant 199 is deposited over interconnect structures 196a and 196b to form encapsulated interconnect e-bar structures 198a and 198b. The e-bar structure comes from core substrate 168 and conductive vias 172 and conductive layers 174, as well as interconnect structures 175 and 179. Encapsulated interconnect e-bar structures 198a and 198b have a height similar to encapsulated interconnect post structures 166a-166c.

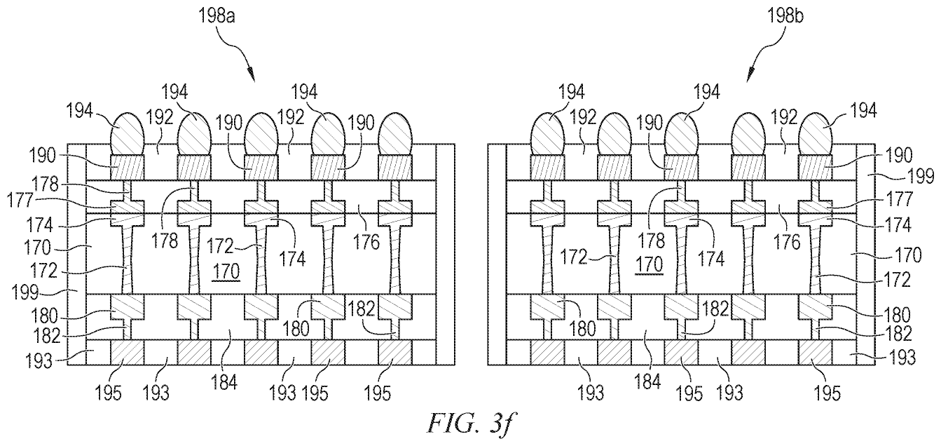

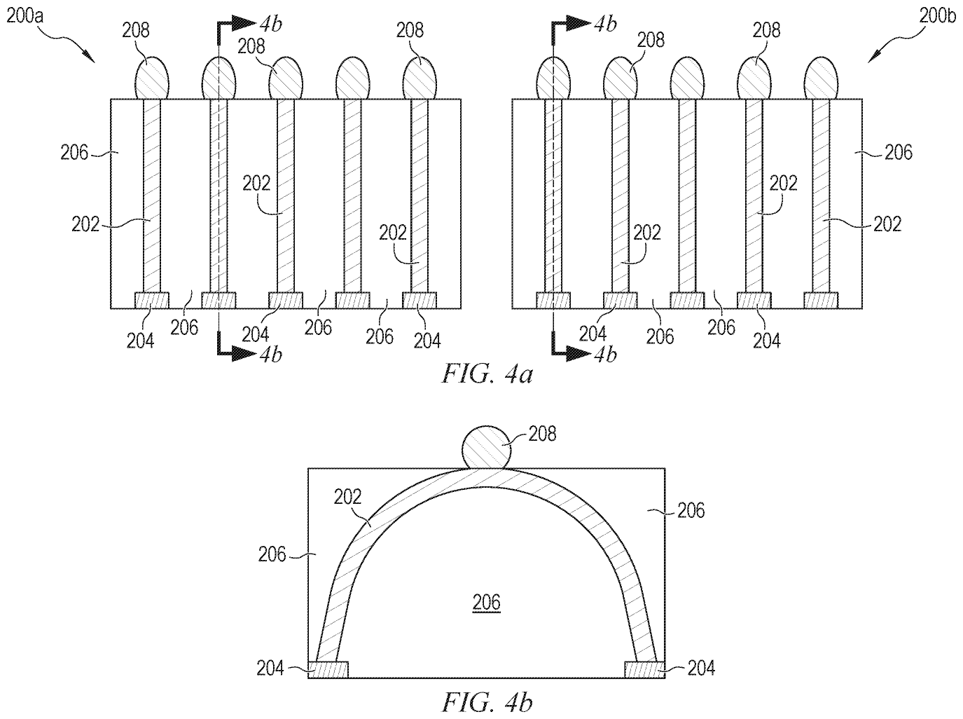

FIG. 4a shows an alternate embodiment of encapsulated interconnect vertical loop structures 200a and 200b. Conductive wires 202 vertically loop over conductive layer 204. FIG. 4b is cross-sectional view of vertical loop conductive wires 202 in a plane normal to FIG. 4a.

An encapsulant or molding compound 206 is deposited over and around conductive wires 202 using a paste printing, compressive molding, transfer molding, liquid encapsulant molding, vacuum lamination, spin coating, or other suitable applicator. Encapsulant 206 can be polymer composite material, such as epoxy resin with filler, epoxy acrylate with filler, or polymer with proper filler. Encapsulant 206 is non-conductive, provides structural support, and environmentally protects the semiconductor device from external elements and contaminants.

An electrically conductive bump material is deposited over conductive wires 202 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive wires 202 using a suitable attachment or bonding process. In one embodiment, the bump material is reflowed by heating the material above its melting point to form balls or bumps 208. In one embodiment, bump 208 is formed over a UBM having a wetting layer, barrier layer, and adhesive layer. Bump 208 can also be compression bonded or thermocompression bonded to conductive wires 202. Bump 208 represents one type of interconnect structure that can be formed over conductive wires 202. The interconnect structure can also use bond wires, conductive paste, stud bump, micro bump, or other electrical interconnect. Encapsulated interconnect vertical loop structures 200a and 200b have a height similar to encapsulated interconnect post structures 166a-166c.

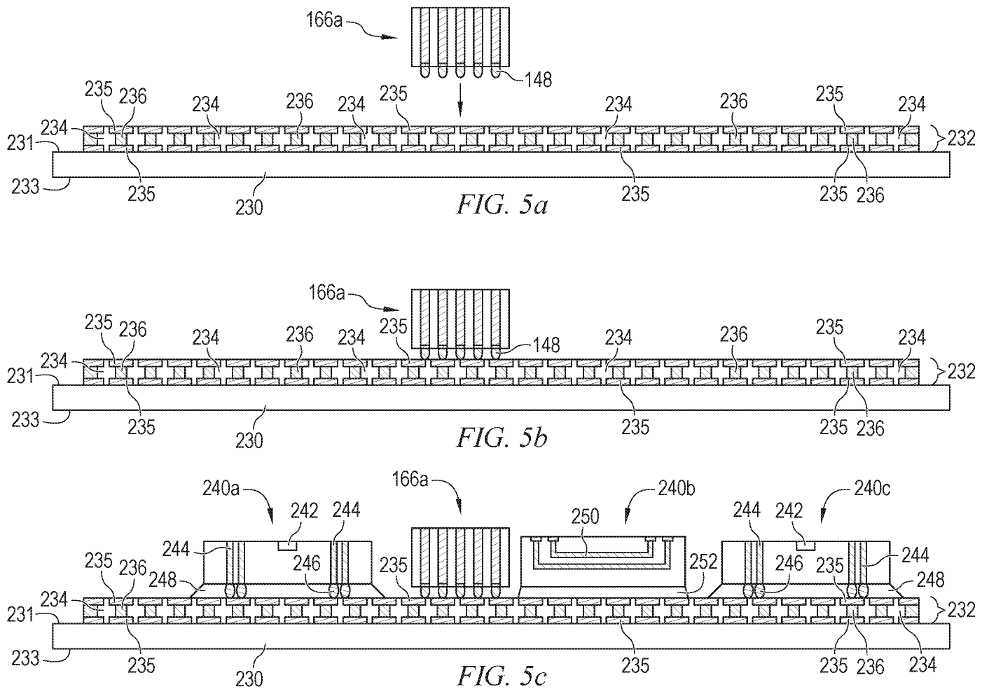

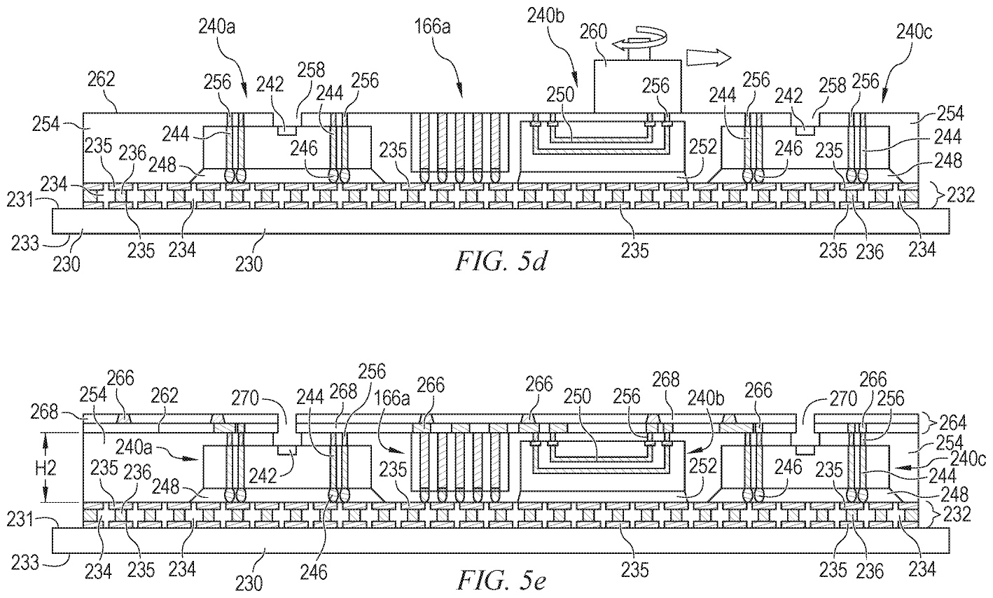

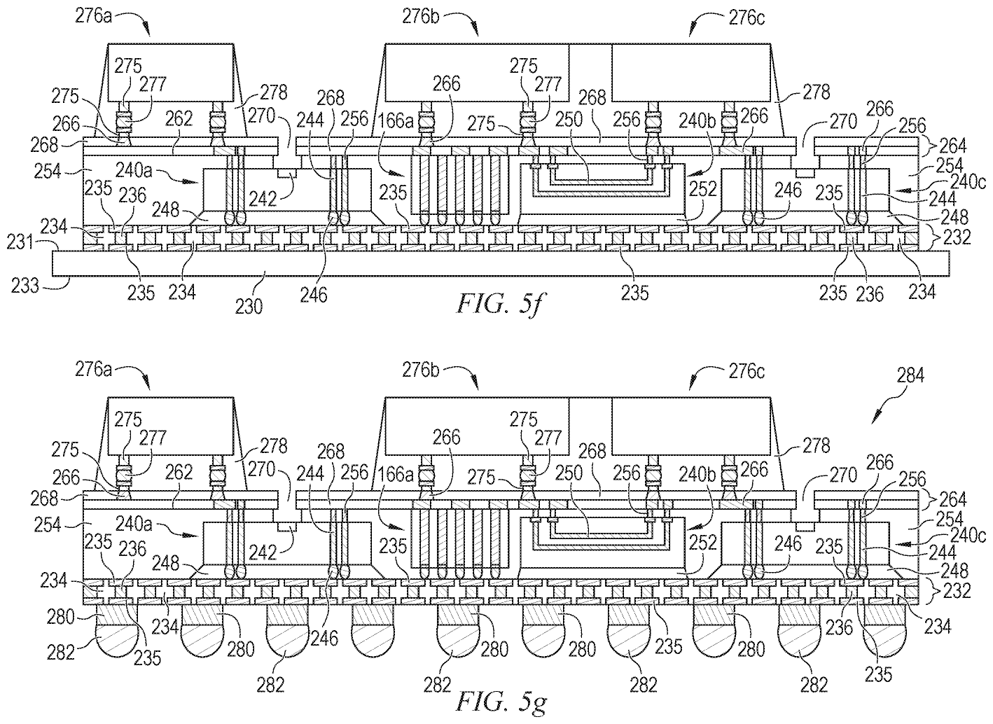

FIG. 5a shows a temporary substrate or carrier 230 containing sacrificial base material, such as silicon, polymer, beryllium oxide, glass, metal, or other suitable low-cost, rigid material for structural support. Substrate 230 has major surface 231 and major surface 233, opposite surface 231. An interconnect structure 232 is formed over surface 231. Interconnect structure 232 includes insulating layer 234, conductive layers 235, and conductive vias 236 formed through the insulating layer, similar to conductive vias 172 and conductive layer 174 in FIG. 3b.

Encapsulated interconnect post structure 166a is positioned over interconnect structure 232 using a pick and place operation. Encapsulated interconnect post structure 166a is mechanically and electrically bonded to conductive layer 235 of interconnect structure 232 by reflowing bumps 148. Encapsulated interconnect post structures 166b and 166c can also be bonded to interconnect structure 232. FIG. 5b shows one encapsulated interconnect post structure 166a mechanically and electrically bonded to interconnect structure 232 to simplify overall structure.

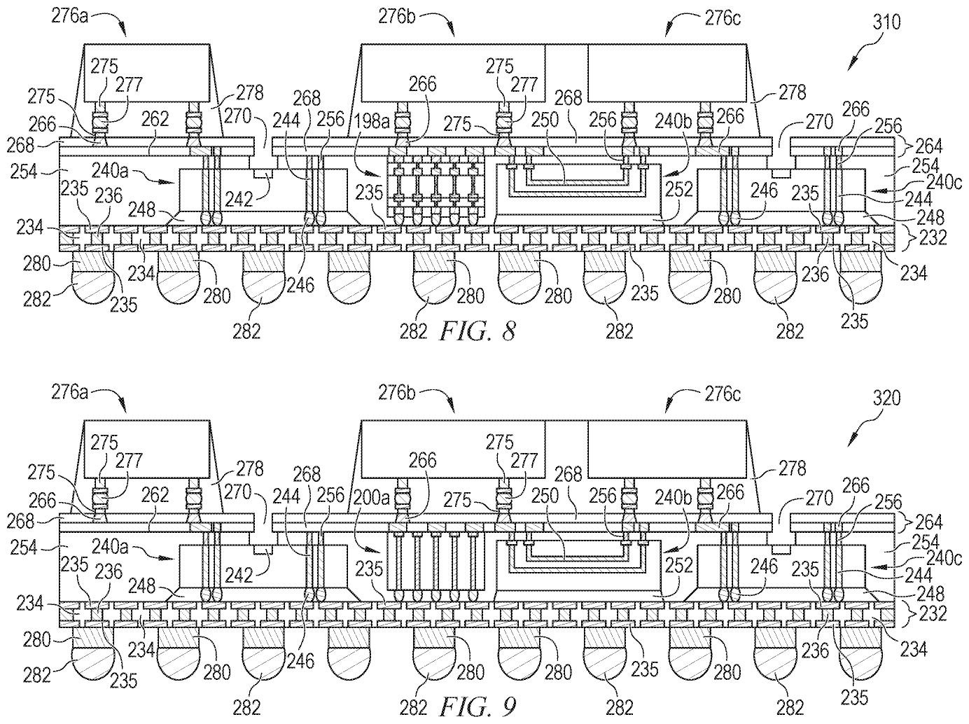

In an alternate embodiment, encapsulated interconnect e-bar structures 198a and 198b from FIG. 3f or encapsulated interconnect vertical loop structures 200a and 200b from FIG. 4a can be mechanically and electrically bonded to interconnect structure 232, see FIGS. 8 and 9. Encapsulated interconnect e-bar structures 198a and 198b and/or encapsulated interconnect vertical loop structures 200a and 200b can be bonded to interconnect structure 232 in lieu of or in addition to encapsulated interconnect post structures 166a-166c.

In FIG. 5c, a plurality of electrical components 240a, 240b, and 240c are each positioned over interconnect structure 232 using a pick and place operation, similar to FIGS. 5a-5b. For example, electrical components 240a-240c can be similar to semiconductor die 104 from FIG. 1c. Alternatively, electrical components 240a-240c can include other semiconductor die, semiconductor packages, surface mount devices, discrete electrical devices, or IPDs. In one embodiment, electrical components 240a and 240c are photonic semiconductor die with photonic or optical area 242, conductive vias 244, bumps 246, and underfill material 248, such as an epoxy resin. Electrical component 240b can be like electrical components 240a, i.e. TSV die with solder interconnection. Photonic area 242 is light sensitive and converts optical energy into electrical signals. Photonic area 242 can be an optical sensor. Electrical component 240b includes conductive layer 250 and underfill material 252, such as an epoxy resin.

The distance between interconnect structure 175 and 179 is height H2 of 150 μm. The height H1 of embedded interconnect post structure 166a is sufficient to span the gap between interconnect structure 175 and 179, i.e., H2, to provide an electrical interconnect between the interconnect structures. The height H1 of embedded interconnect post structure 166a is greater than or equal to a greatest height of electrical components 240a-240c, i.e., height H3 in the range of 300-400 μm, which are disposed between interconnect structures 175 and 179.

In FIG. 5d, an encapsulant or molding compound 254 is deposited over and around encapsulated interconnect post structure 166a and electrical components 240a-240c using a paste printing, compressive molding, transfer molding, liquid encapsulant molding, vacuum lamination, spin coating, or other suitable applicator. Encapsulant 254 can be polymer composite material, such as epoxy resin with filler, epoxy acrylate with filler, or polymer with proper filler. Encapsulant 254 is non-conductive, provides structural support, and environmentally protects the semiconductor device from external elements and contaminants.

A portion of encapsulant 254 is removed by an etching process or LDA to form conductive vias 256 making electrical connection to conductive vias 244. Another portion of encapsulant 254 is removed by an etching process or LDA to form openings 258 and expose photonic area 242 to light. Encapsulant 254 undergoes a grinding operation with grinder 260 to planarize surface 262.

In FIG. 5e, an interconnect structure 264 is formed over surface 262 of encapsulant 254 and includes conductive layers or vias 266 and insulating layers 268, made by processes described herein, such as interconnect structures 175, 179, and 232. A portion of interconnect structure 264 is removed by an etching process or LDA to form openings 270 and expose photonic area 242 to light.

In FIG. 5f, a plurality of electrical components 276a, 276b, and 276c are each positioned over interconnect structure 264 using a pick and place operation, similar to FIGS. 5a-5b. For example, electrical components 276a-276c can be similar to semiconductor die 104 from FIG. 1c. Alternatively, electrical components 276a-276c can include other semiconductor die, semiconductor packages, surface mount devices, discrete electrical devices, or IPDs. Electrical components 276a-276c make mechanical and electrical connect with contacts 275 and bumps 277, made by processes described herein, such as reflow. An underfill material 278, such as epoxy resin, is deposited around electrical components 276a-276c, by processes described herein.

In FIG. 5g, substrate 230 is removed by chemical etching, CMP, mechanical peel-off, mechanical grinding, thermal bake, UV light, or wet stripping to expose insulating layer 234 and conductive layer 235 of interconnect structure 232. Conductive layer 280 is formed over conductive layer 235 and bumps 282 are formed over conductive layer 280, by processes described herein, yielding SiP module 284.

SiP module 284 includes photonic electrical components 240a and 240b, which are typically thick devices. Encapsulated interconnect post structure 166a provides electrical interconnect between interconnect structures 232 and 264 for electrical signals to and from electrical components 240a-240c. Encapsulated interconnect post structure 166a has sufficient height to span the gap between interconnect structures 232 and 264, given the thickness of photonic electrical components 240a and 240b.

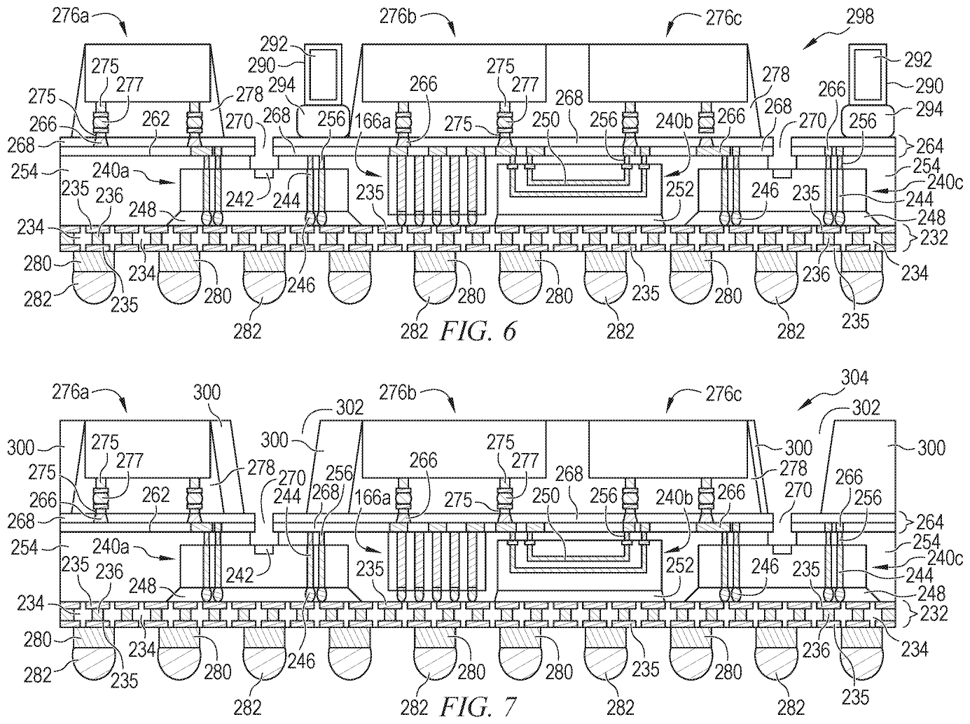

FIG. 6 shows an alternate embodiment, similar to SiP module 284, with stiffener 290 having internal solid core 292 bonded to interconnect structure 264 with adhesive 294. Stiffener 290 has an internal solid core 292, such as metal or polymer. The embodiment in FIG. 6 is referenced as SiP module 298.

FIG. 7 shows an alternate embodiment, similar to SiP module 284, with encapsulant 300 deposited around electrical components 276a-276c and underfill material 278 using a paste printing, compressive molding, transfer molding, liquid encapsulant molding, vacuum lamination, spin coating, or other suitable applicator. Encapsulant 300 can be polymer composite material, such as epoxy resin with filler, epoxy acrylate with filler, or polymer with proper filler. Encapsulant 300 is non-conductive, provides structural support, and environmentally protects the semiconductor device from external elements and contaminants. A portion of encapsulant 300 is removed by an etching process or LDA to form openings 302 and expose photonic area 242 to light. The embodiment in FIG. 7 is referenced as SiP module 304.

FIG. 8 shows an alternate embodiment, similar to SiP module 284, with encapsulated interconnect e-bar structure 198a in lieu of or in addition to encapsulated interconnect post structure 166a. The embodiment in FIG. 8 is referenced as SiP module 310.

FIG. 9 shows an alternate embodiment, similar to SiP module 284, with encapsulated interconnect vertical loop structure 200a in lieu of or in addition to encapsulated interconnect post structure 166a. The embodiment in FIG. 9 is referenced as SiP module 320.

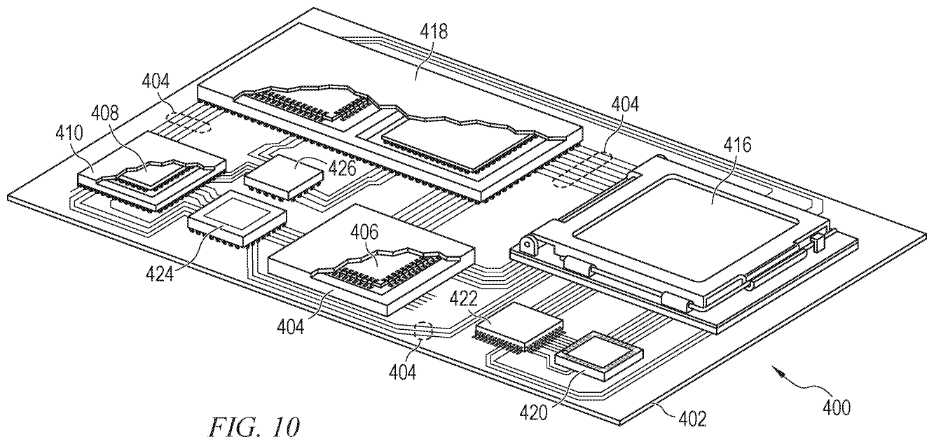

FIG. 10 illustrates electrical device 400 having a chip carrier substrate or PCB 402 with a plurality of semiconductor packages disposed on a surface of PCB 402, including SiP modules 284, 298, 304, 310, and 320. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 10, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a first interconnect structure;
a second interconnect structure;
a semiconductor die disposed between the first interconnect structure and second interconnect structure;
an embedded interconnect structure disposed between the first interconnect structure and second interconnect structure; and
a first encapsulant deposited around the semiconductor die and embedded interconnect structure.

2. The semiconductor device of claim 1, wherein the embedded interconnect structure includes a height sufficient to span a gap between the first interconnect structure and second interconnect structure.

3. The semiconductor device of claim 1, wherein the embedded interconnect structure includes:
a plurality of conductive posts; and
a second encapsulant deposited around the conductive posts.

4. The semiconductor device of claim 1, wherein the embedded interconnect structure includes:
a plurality of e-bar structures; and
a second encapsulant deposited around the e-bar structures.

5. The semiconductor device of claim 1, wherein the embedded interconnect structure includes:
a plurality of vertical loop wires; and
a second encapsulant deposited around the vertical loop wires.

6. The semiconductor device of claim 1, wherein the semiconductor die includes a photonic area.

7. A semiconductor device, comprising:
a semiconductor die;
an embedded interconnect structure having a height greater than or equal to a height of the semiconductor die; and
a first encapsulant deposited around the embedded interconnect structure.

8. The semiconductor device of claim 7, further including:
a first interconnect structure; and
a second interconnect structure, wherein the semiconductor die and embedded interconnect structure are disposed between the first interconnect structure and second interconnect structure.

9. The semiconductor device of claim 7, wherein the embedded interconnect structure includes:
a plurality of conductive posts; and
a second encapsulant deposited around the conductive posts.

10. The semiconductor device of claim 7, wherein the embedded interconnect structure includes:
a plurality of e-bar structures; and
a second encapsulant deposited around the e-bar structures.

11. The semiconductor device of claim 7, wherein the embedded interconnect structure includes:
a plurality of vertical loop wires; and
a second encapsulant deposited around the vertical loop wires.

12. The semiconductor device of claim 7, wherein the semiconductor die includes a photonic area.

13. The semiconductor device of claim 7, wherein the first interconnect structure includes a redistribution layer.

14. A method of making a semiconductor device, comprising:
providing a first interconnect structure;
providing a second interconnect structure;
disposing a semiconductor die between the first interconnect structure and second interconnect structure;
disposing an embedded interconnect structure between the first interconnect structure and second interconnect structure; and
depositing a first encapsulant around the semiconductor die and embedded interconnect structure.

15. The semiconductor device of claim 14, wherein the embedded interconnect structure includes a height sufficient to span a gap between the first interconnect structure and second interconnect structure.

16. The method of claim 14, wherein disposing the embedded interconnect structure includes:
providing a plurality of conductive posts; and
depositing a second encapsulant around the conductive posts.

17. The method of claim 14, wherein disposing the embedded interconnect structure includes:
providing a plurality of e-bar structures; and
depositing a second encapsulant around the e-bar structures.

18. The method of claim 14, wherein disposing the embedded interconnect structure includes:
providing a plurality of vertical loop wires; and
depositing a second encapsulant around the vertical loop wires.

19. The method of claim 14, wherein the semiconductor die includes a photonic area.

20. A method of making a semiconductor device, comprising:
providing a semiconductor die;
providing an embedded interconnect structure having a height greater than or equal to a height of the semiconductor die; and
depositing a first encapsulant around the embedded interconnect structure.

21. The method of claim 20, further including:
providing a first interconnect structure; and
providing a second interconnect structure, wherein the semiconductor die and embedded interconnect structure are disposed between the first interconnect structure and second interconnect structure.

22. The method of claim 20, wherein providing the embedded interconnect structure includes:
providing a plurality of conductive posts; and
depositing a second encapsulant around the conductive posts.

23. The method of claim 20, wherein providing the embedded interconnect structure includes:
providing a plurality of e-bar structures; and
depositing a second encapsulant around the e-bar structures.

24. The method of claim 20, wherein providing the embedded interconnect structure includes:
providing a plurality of vertical loop wires; and
depositing a second encapsulant around the vertical loop wires.

25. The method of claim 20, wherein the semiconductor die includes a photonic area.
